(19) United States
(12) Patent Application Publication
(10) Pub. No.: US 2026/0254413 A1
(43) Pub. Date: Aug. 27, 2026

(54) POWER AMPLIFICATION CIRCUIT

(71) Applicant: Murata Manufacturing Co., Ltd., Nagaokakyo-shi (JP)

(72) Inventor: Shohei IMAI, Nagaokakyo-shi (JP)

(21) Appl. No.: 19/651,048

(22) Filed: Apr. 17, 2026

Related U.S. Application Data
(63) Continuation of application No. PCT/JP2024/038664, filed on Oct. 30, 2024.

(30) Foreign Application Priority Data
Nov. 17, 2023 (JP) 2023-196119

(51) Int. Cl. H03F 1/02; H03F 1/56

(52) U.S. Cl. CPC H03F 1/0288; H03F 1/565; H03F 2200/451; H03F 2200/541

(57) ABSTRACT

Broadband characteristics are implemented even when an impedance is low on an output side when seen from output ends of a carrier amplifier and a peak amplifier included in a Doherty amplifier. A power amplification circuit includes: a carrier amplifier and a peak amplifier included in a Doherty amplifier circuit; a first transformer including a primary winding connected to an output end of the carrier amplifier; a second transformer including a primary winding connected to an output end of the peak amplifier; a signal line connecting one end of a secondary winding included in the first transformer and one end of a secondary winding included in the second transformer to one another; a first capacitor; and second and third capacitors connected to the respective primary windings of the first and second transformers.

### CROSS REFERENCE TO RELATED APPLICATION

This is a continuation of International Application No. PCT/JP2024/038664 filed on Oct. 30, 2024 which claims priority from Japanese Patent Application No. 2023-196119 filed on Nov. 17, 2023. The contents of these applications are incorporated herein by reference in their entireties.

### BACKGROUND OF THE DISCLOSURE

### Field of the Disclosure

The present disclosure relates to a power amplification circuit.

### Description of the Related Art

Shohei Imai et al. “Bandwidth Optimization of Doherty Power Amplifier Based on Source Converters for 5G Mobile Handsets”, IEEE TRANSACTIONS ON MICROWAVE THEORY AND TECHNIQUES, VOL. 70, NO. 1, January 2022 (hereinafter referred to as “Non-Patent Document 1”) discloses a power amplification circuit including a Doherty amplifier configuration. In FIG. 6 of Non-Patent Document 1, a power amplification circuit in the related art is illustrated. The power amplification circuit described in Non-Patent Document 1 has a configuration in which a converter that can be regarded as a current source is connected to an output side of a peak amplifier and a converter that can be regarded as a voltage source is connected to an output side of a carrier amplifier. Non-Patent Document 1 discloses that this configuration achieves a Doherty amplifier having a broad matching fractional bandwidth.

### BRIEF SUMMARY OF THE DISCLOSURE

In the power amplification circuit described in Non-Patent Document 1, the converter that can be regarded as the current source is a converter that outputs a high impedance while keeping it high. On the other hand, the converter that can be regarded as the voltage source is a converter that converts a high impedance into a low impedance and outputs the converted impedance. There is a problem in that when an impedance is low on an output side when seen from output ends of the carrier amplifier and the peak amplifier, obtaining favorable characteristics over a wide frequency band, that is, implementing broadband characteristics is difficult because of a limit of a conversion ratio of the converters.

The present disclosure is made in view of the above problem, and a possible benefit thereof is to provide a power amplification circuit capable of implementing broadband characteristics even when an impedance is low on an output side when seen from output ends of a carrier amplifier and a peak amplifier included in a Doherty amplifier.

To solve the above-described problem and achieve the possible benefit, a power amplification circuit according to an aspect of the present disclosure includes: a carrier amplifier and a peak amplifier included in a Doherty amplifier circuit; a first transformer whose primary side is connected to an output end of the carrier amplifier; a second transformer whose primary side is connected to an output end of the peak amplifier; a signal line connecting one end of a secondary side of the first transformer and one end of a secondary side of the second transformer to one another; and a first capacitor. One end of the first capacitor is connected to the signal line, and the other end of the first capacitor is connected to a reference potential. Formula (1) is satisfied, where a sum total of capacitance values of the first capacitor and the signal line is C_{T}, a used frequency is ω₀ (ω₀=2πf), and a load impedance is Z_{M}.

According to the present disclosure, broadband characteristics can be implemented even when an impedance is low on the output side when seen from the output ends of the carrier amplifier and the peak amplifier included in the Doherty amplifier.

### BRIEF DESCRIPTION OF THE SEVERAL VIEWS OF THE DRAWINGS

FIG. 1 is a block diagram illustrating a power amplification circuit according to a first embodiment of the present disclosure.

FIG. 2 is a block diagram illustrating a power amplification circuit according to a second embodiment of the present disclosure.

FIG. 3 is a block diagram illustrating a power amplification circuit according to a third embodiment of the present disclosure.

FIG. 4 is a block diagram illustrating a power amplification circuit according to a fourth embodiment of the present disclosure.

FIG. 5 is a graph illustrating an example of a matching fractional bandwidth relative to a coupling factor of a transformer.

FIG. 6 is a graph illustrating a relationship between a coupling factor of carrier-side and peak-side transformers and a matching fractional bandwidth.

### DETAILED DESCRIPTION OF THE DISCLOSURE

Hereinafter, embodiments of the present disclosure are described in detail with reference to the drawings. In the following description of each embodiment, components which are the same as or equivalent to those of another embodiment are denoted by the same reference characters, and description thereof is simplified or omitted. The present disclosure is not limited by each embodiment. Further, the components in each embodiment include those easily replaceable by a person skilled in the art, or those substantially identical thereto. Note that configurations described below can be combined as appropriate. Moreover, the configurations can be omitted, replaced, or changed without departing from the spirit of the disclosure.

### First Embodiment

### (Configuration)

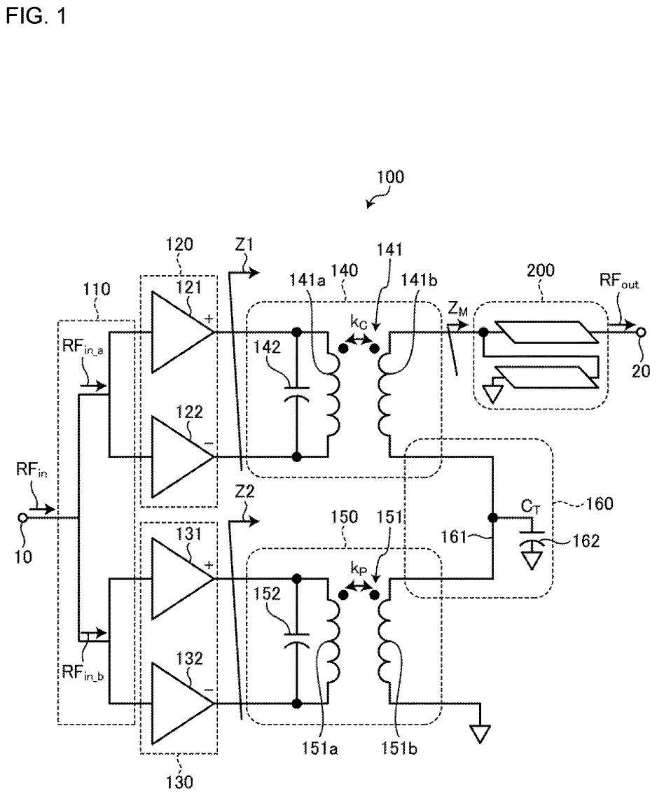

FIG. 1 is a diagram illustrating a power amplification circuit 100 according to a first embodiment of the present disclosure. As illustrated in FIG. 1, the power amplification circuit 100 according to the first embodiment includes an input terminal 10, an output terminal 20, a splitter 110, a carrier amplifier 120, a peak amplifier 130, a converter 140, a converter 150, a connection part 160, and a matching circuit 200. For example, the power amplification circuit 100 is equipped in a cellular phone and used to amplify the power of signals to be transmitted to a base station. For example, the power amplification circuit 100 can amplify the power of signals that comply with communication standards, such as the second-generation mobile communication system (2G), the third-generation mobile communication system (3G), the fourth-generation mobile communication system (4G), the fifth-generation mobile communication system (5G), the long term evolution (LTE)-frequency division duplex (FDD), the LTE-time division duplex (TDD), the LTE-Advanced, and the LTE-Advanced Pro. Note that the communication standards of signals amplified by the power amplification circuit 100 are not limited to those.

The input terminal 10 is a terminal to input an input signal RFin. The output terminal 20 is a terminal to output an output signal RFout.

The power amplification circuit 100 amplifies the input signal RFin inputted to the input terminal 10 and outputs the output signal RFout from the output terminal 20. The input signal RFin is a radio-frequency (RF) signal. A frequency of the input signal RFin is, for example, about a few GHZ.

The splitter 110 splits the input signal RFin into, for example, a signal RFin a and a signal RFin b. The signal RFin b has a phase advanced by approximately 90 degrees from a phase of the signal RFin a. Here, approximately 90 degrees indicates a phase within a range of 90 degrees±45 degrees. Note that in this embodiment, the carrier amplifier 120 and the peak amplifier 130 are differential amplifiers as will be described later. Therefore, each of the signal RFin a and the signal RFin b is further split into two input signals whose phases are different by approximately 180 degrees. Here, approximately 180 degrees indicates a phase within a range of 180 degrees±45 degrees. Note that in FIG. 1, the splitter 110 is formed by a signal line, but the configuration of the splitter is not limited to this. For example, the splitter may be formed by using a transmission line, a 90-degree coupler, a transformer, or the like.

The carrier amplifier 120 and the peak amplifier 130 are included in a Doherty amplifier. For example, the carrier amplifier 120 amplifies the input signal RFin a to output the signal. Moreover, the peak amplifier 130 amplifies the input signal RFin b to output the signal. In this embodiment, for example, the carrier amplifier 120 is biased to be of a class AB, and the peak amplifier 130 is biased to be of a class AB in a level different from the biasing level of the carrier amplifier 120, or a class C.

That is, the carrier amplifier 120 operates regardless of a power level of the input signal RFin within a range where the power level is more than or equal to zero. On the other hand, the peak amplifier 130 operates within a range where a voltage level of the input signal RFin is more than or equal to a level Vback that is lower than a maximum level Vmax by a given level. In other words, the peak amplifier 130 operates within a range where the power level of the input signal RFin is lower than a maximum level by a given level (for example, approximately 6 dB) and higher than or equal to zero. In this manner, a combining operation of the two amplifiers in accordance with the power level of the input signals widens a range where the carrier amplifier 120 operates with a saturation output. Therefore, power efficiency improves as compared with a power amplification circuit including only one amplifier.

Each of the carrier amplifier 120 and the peak amplifier 130 includes a differential amplifier. The differential amplifier includes a pair of two amplifying elements. The carrier amplifier 120 includes a positive-side amplifying element 121 and a negative-side amplifying element 122. The peak amplifier 130 includes a positive-side amplifying element 131 and a negative-side amplifying element 132. Each of the carrier amplifier 120 and the peak amplifier 130 is the differential amplifier, and thereby amplifies the potential difference of signals with the same amplitude and the opposite phases inputted into the respective ones of the two amplifying elements, and outputs the signals. Therefore, in a case in which the signals with the same amplitude and the same phase (for example, noise) are simultaneously inputted into the respective ones of the two amplifying elements, the signals with the same amplitude and the same phase are canceled out. That is, by the differential amplifier being used for each of the carrier amplifier 120 and the peak amplifier 130, occurrence of noise and harmonic waves of input signals can be suppressed.

Note that the amplifying element included in the differential amplifier is not particularly limited, but may be, for example, a bipolar transistor such as a heterojunction bipolar transistor (HBT), or a field-effect transistor such as a metal-oxide-semiconductor field effect transistor (MOSFET).

The converter 140 is connected to an output side of the carrier amplifier 120. The converter 150 is connected to an output side of the peak amplifier 130. For example, the converters 140 and 150 convert characteristics (impedances, phases, and the like) related to the respective ones of the carrier amplifier 120 and the peak amplifier 130 and output the amplified power toward the output terminal 20.

The converter 140 includes a transformer 141 as a first transformer and a capacitor 142. The transformer 141 includes an input-side winding (that is, a primary winding) 141a and an output-side winding (that is, a secondary winding) 141b. In the transformer 141, the input-side winding 141a and the output-side winding 141b are electromagnetically coupled to one another, and a coupling factor thereof is kc.

The capacitor 142 is connected to the input-side winding 141a in parallel. One end of the input-side winding 141a is connected to an output end of the amplifying element 121. The other end of the input-side winding 141a is connected to an output end of the amplifying element 122. One end of the output-side winding 141b is connected to the connection part 160. The other end of the output-side winding 141b is connected to the matching circuit 200.

The converter 150 includes a transformer 151 as a second transformer and a capacitor 152. The transformer 151 includes an input-side winding (that is, a primary winding) 151a and an output-side winding (that is, a secondary winding) 151b. In the transformer 151, the input-side winding 151a and the output-side winding 151b are electromagnetically coupled to one another, and a coupling factor thereof is kp.

The capacitor 152 is connected to the input-side winding 151a in parallel. One end of the input-side winding 151a is connected to an output end of the amplifying element 131. The other end of the input-side winding 151a is connected to an output end of the amplifying element 132. One end of the output-side winding 151b is connected to the connection part 160. The other end of the output-side winding 151b is connected to a reference potential. The connection part 160 has a function to connect the converter 140 that can be regarded as a current source and the converter 150 that can be regarded as a voltage source to one another. Note that details of a converter that can be regarded as a current source are disclosed in Non-Patent Document 1, and thereby description herein is omitted.

The matching circuit 200 is provided between the other end of the output-side winding 141b of the converter 140 and the output terminal 20. That is, the other end of the output-side winding 141b of the converter 140 is connected to the output terminal 20 with the matching circuit 200 interposed therebetween. The matching circuit 200 is, for example, a matching circuit including a transmission line transformer (TLT).

The connection part 160 includes a signal line 161 and a capacitor 162. The signal line 161 electrically connects the output-side winding 141b of the converter 140 and the output-side winding 151b of the converter 150 to one another. The signal line 161 electrically connects the one end of the output-side winding 141b of the converter 140 and the one end of the output-side winding 151b of the converter 150 to one another. One end of the capacitor 162 is connected to the signal line 161. The other end of the capacitor 162 is connected to the reference potential.

### Effects

According to the power amplification circuit 100 of the first embodiment, broadband characteristics can be implemented even when impedances Z1 and Z2 on the output side when seen from the output ends of the carrier amplifier 120 and the peak amplifier 130 are low. Note that details of the effects and details of a condition to achieve the effects will be described later.

### Second Embodiment

### (Configuration)

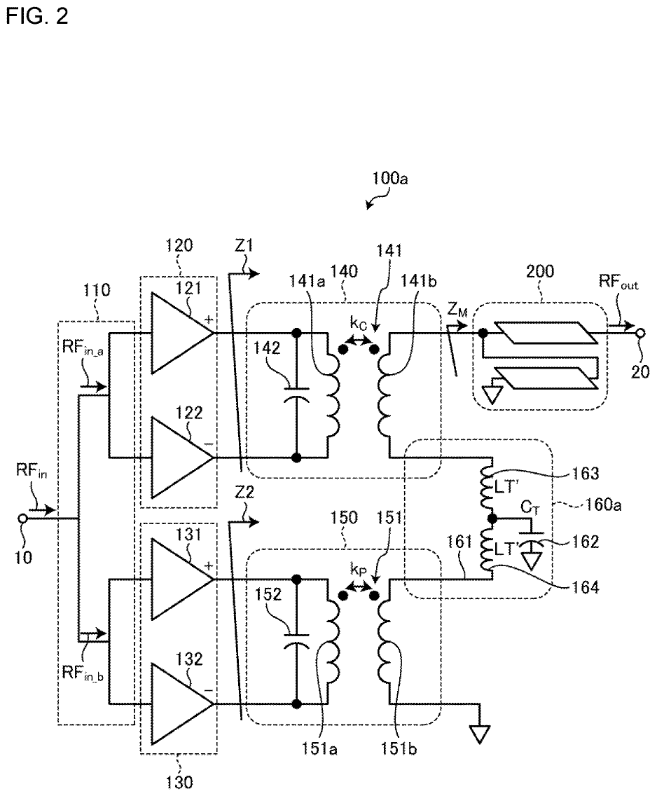

FIG. 2 is a diagram illustrating a power amplification circuit 100a according to a second embodiment of the present disclosure. The power amplification circuit 100a of this embodiment is different from the power amplification circuit 100 of the first embodiment in that a connection part 160a is used instead of the connection part 160. The connection part 160a includes inductors 163 and 164. That is, the power amplification circuit 100a of this embodiment has the configuration in which the inductors 163 and 164 are added to the power amplification circuit 100 of the first embodiment.

### Effects

According to the power amplification circuit 100a of the second embodiment, broadband characteristics can be implemented even when the impedances Z1 and Z2 on the output side when seen from the output ends of the carrier amplifier 120 and the peak amplifier 130 are low. Note that details of the effects and details of a condition to achieve the effects will be described later.

### Third Embodiment

### (Configuration)

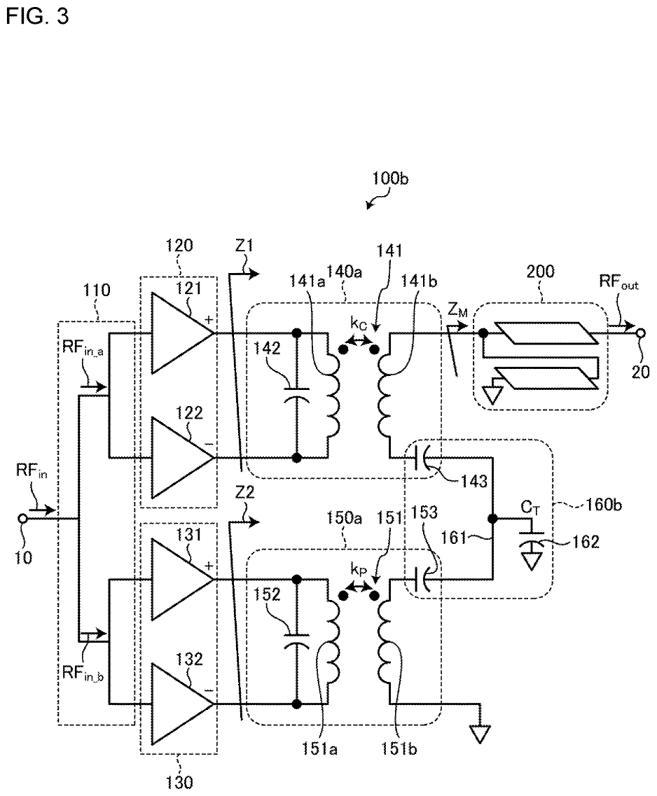

FIG. 3 is a diagram illustrating a power amplification circuit 100b according to a third embodiment of the present disclosure. The power amplification circuit 100b of this embodiment is different from the power amplification circuit 100 of the first embodiment in that a connection part 160b is used instead of the connection part 160. The connection part 160b includes capacitors 143 and 153. That is, the power amplification circuit 100b of this embodiment has the configuration in which the capacitors 143 and 153 are added to the power amplification circuit 100 of the first embodiment. The capacitor 143 can be considered as a component of a converter 140a. The converter 140a has the configuration in which the capacitor 143 is added to the converter 140 of the power amplification circuit 100. The capacitor 153 can be considered as a component of a converter 150a. The converter 150a has the configuration in which the capacitor 153 is added to the converter 150 of the power amplification circuit 100.

### Effects

According to the power amplification circuit 100b of the third embodiment, broadband characteristics can be implemented even when the impedances Z1 and Z2 on the output side when seen from the output ends of the carrier amplifier 120 and the peak amplifier 130 are low. Note that details of the effects and details of a condition to achieve the effects will be described later.

### Fourth Embodiment

### (Configuration)

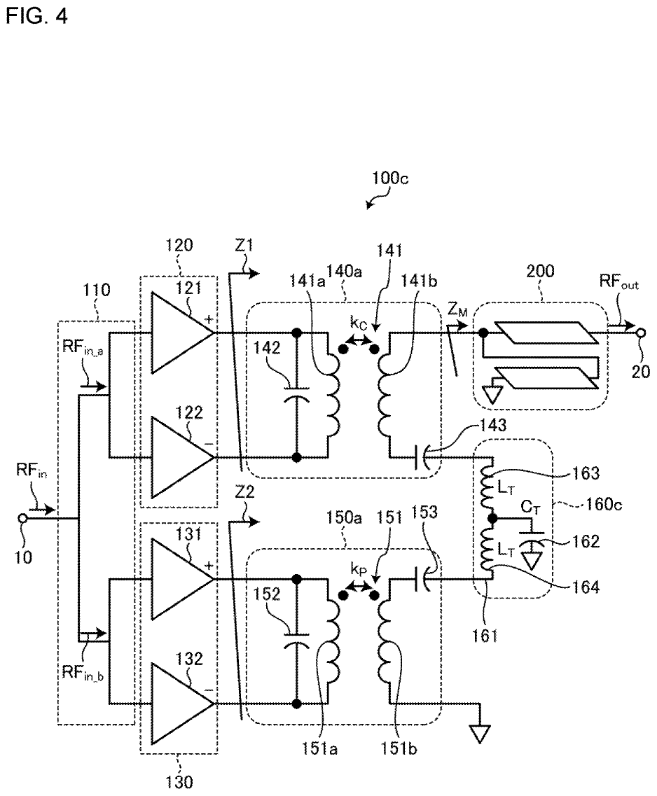

FIG. 4 is a diagram illustrating a power amplification circuit 100c according to a fourth embodiment of the present disclosure. The power amplification circuit 100c of this embodiment is different from the power amplification circuit 100 of the first embodiment in that the converter 140a is used instead of the converter 140, the converter 150a is used instead of the converter 150, and a connection part 160c is used instead of the connection part 160.

The converter 140a includes the capacitor 143. The converter 140a has the configuration in which the capacitor 143 is added to the converter 140 of the power amplification circuit 100. The converter 150a includes the capacitor 153. The converter 150a has the configuration in which the capacitor 153 is added to the converter 150 of the power amplification circuit 100.

The connection part 160c includes the inductors 163 and 164. One end of the inductor 163 is connected to the capacitor 143. The other end of the inductor 163 is connected to the one end of the capacitor 162. One end of the inductor 164 is connected to the capacitor 153. The other end of the inductor 164 is connected to the one end of the capacitor 162. The other end of the capacitor 162 is connected to the reference potential.

### Effects

According to the power amplification circuit 100c of the fourth embodiment, broadband characteristics can be implemented even when the impedances Z1 and Z2 on the output side when seen from the output ends of the carrier amplifier 120 and the peak amplifier 130 are low. Note that details of the effects and details of a condition to achieve the effects will be described later.

Next, a condition to implement each embodiment described above will be described. In order to implement each embodiment, a condition of each formula described below needs to be satisfied.

### Condition to Implement First Embodiment

In order to implement the first embodiment, the following Formula (1) needs to be satisfied. In Formula (1), assume that a sum total of a capacitance value of the capacitor 162 is C_{T}, an angular frequency is ω₀ (2πf), and a load impedance on a load side when seen from the output-side winding 141b of the converter 140 is Z_{M}. Note that the sum total C_{T} includes capacitance of the signal line 161 with respect to the reference potential. Further, a frequency f used to obtain the angular frequency ω₀ is a frequency used in the power amplification circuit 100, and is, for example, a frequency of a signal inputted into the power amplification circuit 100. When Formula (1) is satisfied, the sum total C_{T} falls within a range of ±50% of a load impedance substantially at the used frequency, and thereby the first embodiment can be implemented.

$$0.5 \times \frac{2}{{Z}_{M} {ω}_{0}} < {C}_{T} < 1.5 \times \frac{2}{{Z}_{M} {ω}_{0}} \qquad ( 1 )$$

In addition, the following Formula (2) needs to be satisfied. In Formula (2), a ratio Zₜₐᵣ/Z_{M} is a ratio of a target impedance Zₜₐᵣ to the load impedance Z_{M}. The load impedance Z_{M} is an impedance on the output terminal 20 side when seen from the converter 140 in FIG. 1. When Formula (2) is satisfied, the coupling factors kc and kp are included in a range of 0.35≤k≤0.95 where broadband characteristics can be implemented as will be described later. Therefore, in the first embodiment, a wide matching fractional bandwidth can be implemented. Further, in Formula (2), in a case in which the ratio Zₜₐᵣ/Z_{M} is included in a range of 0.09<Zₜₐᵣ/Z_{M}<8.64, the coupling factors kc and kp are included in a range of 0.4≤k≤0.85 where broadband characteristics and a matching fractional bandwidth with a wider extension width than that in the related art can more reliably be implemented as will be described later.

$$0.01 < \frac{{Z}_{tar}}{{Z}_{M}} < 12.32 \qquad ( 2 )$$

Note that in Formula (2), Zₜₐᵣ can be approximately estimated based on the following Formula (3).

$${Z}_{tar} = \frac{{V}_{cc}^{2}}{\frac{Pout}{{N}_{cell} {η}_{Loss}}} \qquad ( 3 )$$

Note that in Formula (3), V_{cc} is the supply voltage and Pout is the saturation output voltage, and both of them are measurable values. N_{cell} is a number of amplifiers included, and is a fixed value “4” in this embodiment. η_{Loss} is a measurable value from 80% to 90% (that is, from 0.8 to 0.9) as a general value, and a general representative value is 85% (0.85).

### Condition to Implement Second Embodiment

In order to implement the second embodiment, the above-described Formula (1) and the following Formula (4) need to be satisfied.

$$\frac{\frac{{Z}_{M}}{2 {ω}_{0}} - {L}_{T}^{′}}{{C}_{1} {Z}_{M} {Z}_{tar}} < 9 \text{.26} \qquad ( 4 )$$

In Formula (4), an inductance value L_{T}′ is an inductance value of each of the inductors 163 and 164. In Formula (4), C1 is a capacitance value of each of the capacitors 142 and 152. When Formula (4) is satisfied, the coupling factors kc and kp are included in a range of 0.35≤k<1.0 where broadband characteristics can be implemented as will be described later. Therefore, in the second embodiment, a wide matching fractional bandwidth can be implemented. Further, when Formula (4) where the right side is 2.60 is satisfied, the coupling factors kc and kp are included in a range of k≤0.85 where a matching fractional bandwidth with a wider extension width than that in the related art can be implemented as will be described later.

### Condition to Implement Third Embodiment

In order to implement the third embodiment, the above-described Formula (1) and the following Formula (5) need to be satisfied.

$$0.14 < \frac{1 + \frac{{ω}_{0} {Z}_{M}}{2} {C}_{2}^{′}}{{Z}_{M} {Z}_{tar} {ω}_{0}^{2} {C}_{1} {C}_{2}^{′}} \qquad ( 5 )$$

In Formula (5), C1 is the capacitance value of each of the capacitors 142 and 152. Further, assuming that a capacitance value of the capacitor 153 is C2, C2′=C2/(1−ω₀²L_{T}C₂) is established. When Formula (5) is satisfied, the coupling factors kc and kp are included in a range of 0.35≤k≤0.95 where broadband characteristics can be implemented as will be described later. Therefore, in the third embodiment, a wide matching fractional bandwidth can be implemented. Further, when Formula (5) where the left side is 0.19 is satisfied, the coupling factors kc and kp are included in a range of 0.4≤k where broadband characteristics can more reliably be implemented as will be described later.

### Condition to Implement Fourth Embodiment

In order to implement the fourth embodiment, the connection part 160c needs to operate as a ¼ wavelength line. The inductors 163 and 164 and the capacitor 162, which are lumped components, implement the ¼ wavelength line and can implement operation as the Doherty amplifier.

### (Relationship Between Transformer Coupling Factor and Matching Fractional Bandwidth)

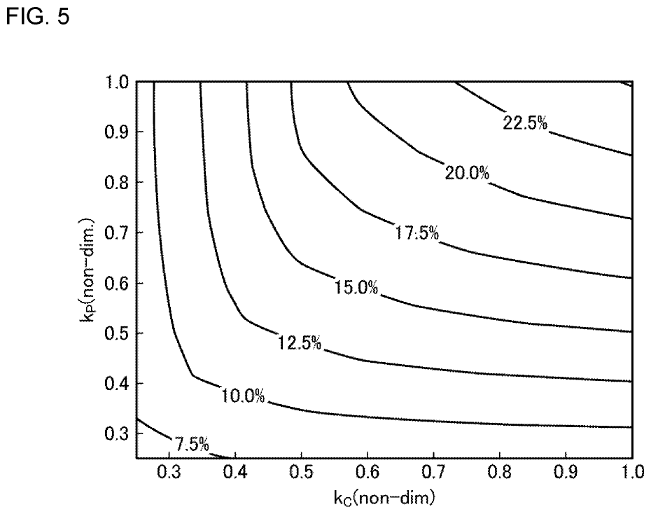

FIG. 5 is a graph illustrating an example of a matching fractional bandwidth relative to a coupling factor of a transformer. FIG. 5 is a diagram corresponding to FIG. 16 of Non-Patent Document 1. In FIG. 5, a horizontal axis indicates the coupling factor kc between the input-side winding 141a and the output-side winding 141b of the carrier-side transformer 141. A vertical axis indicates the coupling factor kp between the input-side winding 151a and the output-side winding 151b of the peak-side transformer 151. It can be understood from FIG. 5 and the description in Non-Patent Document 1 that the power amplification circuit in the related art can realize the matching fractional bandwidth of 7.5% at the minimum. That is, it can be said that the matching fractional bandwidth of more than or equal to 7.5% can implement characteristics substantially equivalent to those in Non-Patent Document 1, that is, broadband characteristics as said in Non-Patent Document 1. Note that the matching fractional bandwidth is a value (%) obtained by dividing a difference between an upper-limit value and a lower-limit value of a frequency band by an average of the upper-limit value and the lower-limit value.

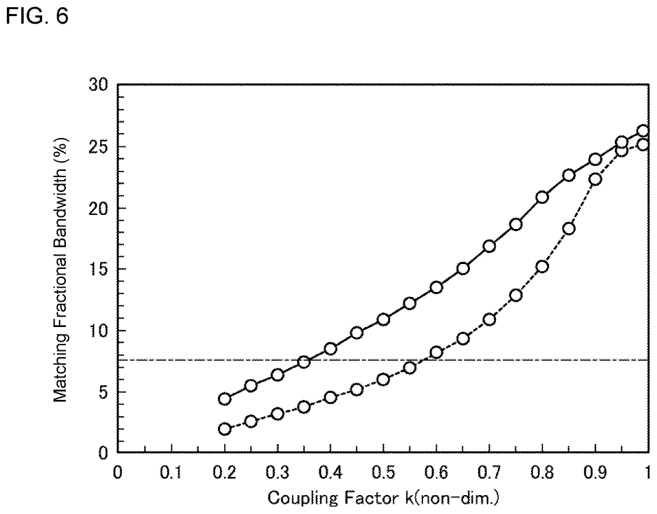

FIG. 6 is a graph illustrating a relationship between a coupling factor k and the matching fractional bandwidth assuming that the coupling factors of the carrier-side transformer and the peak-side transformer are the same. A broken line in FIG. 6 indicates a relationship between the coupling factor and the matching fractional bandwidth with the circuit configuration illustrated in FIG. 6 of Non-Patent Document 1. A solid line in FIG. 6 indicates a relationship between the coupling factor and the matching fractional bandwidth of the power amplification circuit (specifically, the power amplification circuit 100c according to the fourth embodiment) of the present disclosure. A one-dot chain line in FIG. 6 corresponds to the matching fractional bandwidth of 7.5%. Note that in FIG. 6, characteristics of the circuit illustrated in FIG. 6 of Non-Patent Document 1, which are indicated by the broken line, and characteristics of the power amplification circuit of the present disclosure are calculated while parameters related to the respective circuits are set to be the same conditions described below. That is, each parameter is calculated in such a manner that the target impedance Zₜₐᵣ is 5Ω, a designed center frequency f0 is 3.75 GHZ, the load impedance Z_{M} is 27.2Ω, and an inductance product ζ is 16.5Ω.

As described above, it can be said that broadband characteristics can be implemented when the matching fractional bandwidth is more than or equal to 7.5% 7.5%. Therefore, as indicated by the broken line in FIG. 6, the circuit configuration illustrated in FIG. 6 of Non-Patent Document 1 can implement broadband characteristics when the coupling factor k is more than or equal to approximately 0.57. On the other hand, as indicated by the solid line in FIG. 6, the power amplification circuit of the present disclosure can implement broadband characteristics when the coupling factor k is more than or equal to approximately 0.35. That is, the power amplification circuit of the present disclosure can implement broadband characteristics with the lower coupling factor. In other words, the power amplification circuit of the present disclosure can implement broadband characteristics even when the impedances Z1 and Z2 on the output side when seen from the output ends of the carrier amplifier 120 and the peak amplifier 130 are low.

Here, an upper-limit value of the coupling factor is theoretically 1.0. It can be understood that the power amplification circuit of the present disclosure can obtain characteristics more favorable than those of the circuit configuration of Non-Patent Document 1 even with the coupling factor of approximately 0.95 that is close to the upper-limit value. In this way, it can be understood that the power amplification circuit of the present disclosure can implement a matching fractional bandwidth more than or equal to that of the power amplification circuit in the related art when the coupling factor k is 0.35 or more and less than 1.0. Further, it can be understood that the power amplification circuit of the present disclosure can implement a matching fractional bandwidth wider than that of the power amplification circuit in the related art in a range in which the coupling factor is 0.35 or more and 0.95 or less. In addition, it can be understood that characteristics more favorable than those of the circuit configuration of Non-Patent Document 1 are reliably obtained in a range in which the coupling factor is 0.4 or more. Moreover, it can be understood that in a range in which the coupling factor is 0.85 or less, a matching fractional bandwidth wider than that of the power amplification circuit in the related art by 5 points or more can be implemented, and an extension width of the matching fractional bandwidth is comparatively large.

The present disclosure may be in the following modes with regard to the claims.

<1> A power amplification circuit including: a carrier amplifier and a peak amplifier included in a Doherty amplifier circuit; a first transformer including a primary winding connected to an output end of the carrier amplifier; a second transformer including a primary winding connected to an output end of the peak amplifier; a signal line connecting one end of a secondary winding included in the first transformer and one end of a secondary winding included in the second transformer to one another; a first capacitor; a second capacitor connected to the primary winding of the first transformer in parallel; and a third capacitor connected to the primary winding of the second transformer in parallel, in which one end of the first capacitor is connected to the signal line, the other end of the first capacitor is connected to a reference potential, and Formula (1) is satisfied, where a sum total of capacitance values of the first capacitor and the signal line is C_{T}, an angular frequency is ω₀, and a load impedance is Z_{M}.

<2> The power amplification circuit according to <1>, in which a ratio Zₜₐᵣ/Z_{M} of a target impedance Zₜₐᵣ to the load impedance Z_{M} satisfies Formula (2).

<3> The power amplification circuit according to <1> or <2>, further including: a first inductor connected in series between the one end of the first capacitor and the secondary winding of the first transformer; and a second inductor connected in series between the one end of the first capacitor and the secondary winding of the second transformer.

<4> The power amplification circuit according to <3>, in which Formula (4) is satisfied, where an inductance value of the first inductor is L_{T}′ and a capacitance value of the second capacitor is C1, and an inductance value of the second inductor is L_{T}′ and a capacitance value of the third capacitor is C1.

<5> The power amplification circuit according to <1> or <3>, further including: a fourth capacitor connected in series between the one end of the first capacitor and a secondary side of the first transformer; and a fifth capacitor connected in series between the one end of the first capacitor and a secondary side of the second transformer.

<6> The power amplification circuit according to <5>, in which Formula (5) is satisfied, where a capacitance value of the fourth capacitor and a capacitance value of the fifth capacitor are C2 and a capacitance value C2′=C2/(1−ω₀²L_{T}C₂) is established.

<7> The power amplification circuit according to any one of <1> to <6>, in which the other end of a secondary side of the first transformer is connected to an output terminal with a matching circuit interposed therebetween, and the other end of a secondary side of the second transformer is connected to a reference potential.

<8> A power amplification circuit including: a carrier amplifier and a peak amplifier included in a Doherty amplifier circuit; a first transformer whose primary side is connected to an output end of the carrier amplifier; a second transformer whose primary side is connected to an output end of the peak amplifier; a signal line connecting one end of a secondary side of the first transformer and one end of a secondary side of the second transformer to one another; and a first capacitor, in which one end of the first capacitor is connected to the signal line, the other end of the first capacitor is connected to a reference potential, Formula (1) is satisfied, where a sum total of capacitance values of the first capacitor and the signal line is C_{T}, a used frequency is ω₀, and a load impedance is Z_{M}, and a ratio Zₜₐᵣ/Z_{M} of a target impedance Zₜₐᵣ to the load impedance Z_{M} satisfies Formula (2).

<9> A power amplification circuit including: a carrier amplifier and a peak amplifier included in a Doherty amplifier circuit; a first transformer whose primary side is connected to an output end of the carrier amplifier; a second transformer whose primary side is connected to an output end of the peak amplifier; a signal line connecting one end of a secondary side of the first transformer and one end of a secondary side of the second transformer to one another; and a first capacitor, in which one end of the first capacitor is connected to the signal line, the other end of the first capacitor is connected to a reference potential, Formula (1) is satisfied, where a sum total of capacitance values of the first capacitor and the signal line is C_{T}, a used frequency is ω₀, and a load impedance is Z_{M}, a ratio Zₜₐᵣ/Z_{M} of a target impedance Zₜₐᵣ to the load impedance Z_{M} satisfies Formula (2), the power amplification circuit further includes a first inductor connected between the one end of the first capacitor and the secondary side of the first transformer, and a second inductor connected between the one end of the first capacitor and the secondary side of the second transformer, and Formula (4) is satisfied, where inductance values of the first inductor, the second inductor, and the signal line are L_{T}, and L_{T}′=L_{T}−(1/ω₀²C₂) is established.

<10> A power amplification circuit including: a carrier amplifier and a peak amplifier included in a Doherty amplifier circuit; a first transformer whose primary side is connected to an output end of the carrier amplifier; a second transformer whose primary side is connected to an output end of the peak amplifier; a signal line connecting one end of a secondary side of the first transformer and one end of a secondary side of the second transformer to one another; and a first capacitor, in which one end of the first capacitor is connected to the signal line, the other end of the first capacitor is connected to a reference potential, Formula (1) is satisfied, where a sum total of capacitance values of the first capacitor and the signal line is C_{T}, a used frequency is ω₀, and a load impedance is Z_{M}, the power amplification circuit further includes a second capacitor connected in series between the one end of the first capacitor and the secondary side of the first transformer, and a third capacitor connected in series between the one end of the first capacitor and the secondary side of the second transformer, and Formula (5) is satisfied, where a capacitance value of the third capacitor is C2 and a capacitance value C2′=C2/(1−ω₀²L_{T}C₂) is established.

<11> A power amplification circuit including: a carrier amplifier and a peak amplifier included in a Doherty amplifier circuit; a first transformer whose primary side is connected to an output end of the carrier amplifier; a second transformer whose primary side is connected to an output end of the peak amplifier; a signal line connecting one end of a secondary side of the first transformer and one end of a secondary side of the second transformer to one another; and a first capacitor, in which one end of the first capacitor is connected to the signal line, the other end of the first capacitor is connected to a reference potential, Formula (1) is satisfied, where a sum total of capacitance values of the first capacitor and the signal line is C_{T}, a used frequency is ω₀, and a load impedance is Z_{M}, the power amplification circuit further includes a first inductor connected between the one end of the first capacitor and the secondary side of the first transformer, and a second inductor connected between the one end of the first capacitor and the secondary side of the second transformer, and a second capacitor connected in series between the one end of the first capacitor and the secondary side of the first transformer, and a third capacitor connected in series between the one end of the first capacitor and the secondary side of the second transformer.
10 input terminal
20 output terminal
100, 100a, 100b, 100c power amplification circuit
110 splitter
120 carrier amplifier
121, 122, 131, 132 amplifying element
130 peak amplifier
140, 140a converter
141, 151 transformer
141a, 151a input-side winding
141b, 151b output-side winding
142, 143, 152, 153, 162 capacitor
150, 150a converter
160, 160a, 160b, 160c connection part
161 signal line
163, 164 inductor
200 matching circuit

1. A power amplification circuit comprising:
a carrier amplifier and a peak amplifier included in a Doherty amplifier circuit;
a first transformer comprising a primary winding connected to an output of the carrier amplifier;
a second transformer comprising a primary winding connected to an output of the peak amplifier;
a signal line connecting a first end of a secondary winding of the first transformer and a first end of a secondary winding of the second transformer to one another;
a first capacitor;
a second capacitor connected to the primary winding of the first transformer in parallel; and
a third capacitor connected to the primary winding of the second transformer in parallel,
wherein a first end of the first capacitor is connected to the signal line,
wherein a second end of the first capacitor is connected to a reference potential, and
wherein
$$0.5 \times \frac{2}{{Z}_{M} {ω}_{0}} < {C}_{T} < 1.5 \times \frac{2}{{Z}_{M} {ω}_{0}} \qquad ( 1 )$$
where C_{T} is a sum total of capacitance values of the first capacitor and the signal line, ω₀ is an angular frequency, and Z_{M} is a load impedance

2. The power amplification circuit according to claim 1, wherein a ratio Zₜₐᵣ/Z_{M} of a target impedance Zₜₐᵣ to the load impedance Z_{M} satisfies:
$$0.01 < \frac{{Z}_{tar}}{{Z}_{M}} < 12.32 \qquad ( 2 )$$

3. The power amplification circuit according to claim 1, further comprising:
a first inductor connected in series between the first end of the first capacitor and the secondary winding of the first transformer; and
a second inductor connected in series between the first end of the first capacitor and the secondary winding of the second transformer.

4. The power amplification circuit according to claim 3, wherein
$$\frac{\frac{{Z}_{M}}{2 {ω}_{0}} - {L}_{T}^{′}}{{C}_{1} {Z}_{M} {Z}_{tar}} < 9 \text{.26} \qquad ( 4 )$$
where L_{T}′ is an inductance value of the first and second inductors, and C₁ is a capacitance value of the second and third capacitors.

5. The power amplification circuit according to claim 1, further comprising:
a fourth capacitor connected in series between the first end of the first capacitor and the secondary winding of the first transformer; and
a fifth capacitor connected in series between the first end of the first capacitor and the secondary winding of the second transformer.

6. The power amplification circuit according to claim 5, wherein
$$0.14 < \frac{1 + \frac{{ω}_{0} {Z}_{M}}{2} {C}_{2}^{′}}{{Z}_{M} {Z}_{tar} {ω}_{0}^{2} {C}_{1} {C}_{2}^{′}} \qquad ( 5 )$$
where C₂ is a capacitance value of the fourth and fifth capacitors, and C2′=C2/(1−ω₀²L_{T}C₂).

7. The power amplification circuit according to claim 1,
wherein a second end of the secondary winding of the first transformer is connected to an output terminal with a matching circuit interposed therebetween, and
a second end of the secondary winding of the second transformer is connected to a reference potential.
